(19) United States
(12) Patent Application Publication
(10) Pub. No.: US 2015/0189761 A1
(43) Pub. Date: Jul. 2, 2015

(54) METHOD FOR DEPOSITING AND CURING NANOPARTICLE-BASED INK

(71) Applicant: Intrinsiq Materials, Inc., Rochester, NY (US)

(72) Inventors: Chun Wong Aaron Chan, Harrow (GB); Richard John Dixon, Swindon (GB); Michael J. Carmody, Webster, NY (US); Kai Man Kerry Yu, Stockton-on-Tees (GB); Hsin-Yi Sherry Tsai, Rochester, NY (US); Glenn Shackleford, Aldershot (GB); Janet Heyen, Penfield, NY (US)

(21) Appl. No.: 14/568,168

(22) Filed: Dec. 12, 2014

Related U.S. Application Data
(60) Provisional application No. 61/918,945, filed on Dec. 20, 2013.

(51) Int. Cl. H05K 3/12; C09D 11/52; H05K 3/26; H01B 1/02; H01L 21/02; H05K 3/22

(52) U.S. Cl. CPC H05K 3/125; H01L 21/02532; H05K 3/227; H05K 3/26; H05K 3/1291; H01B 1/02; C09D 11/52

(57) ABSTRACT

A method for forming a conductive pattern on a substrate deposits, onto a surface of the substrate, a nanoparticle ink that comprises nanoparticles of a conductive or semiconductor material, at least one low boiling point solvent, and from 0.1 weight % to 50 weight % of a high boiling point solvent. The method forms a partially wet patterned substrate by drying the deposited nanoparticle ink to a wetness range between about 3 weight % and 8 weight % solvent. The method directs a patterned illumination of laser light to cure the deposited ink pattern on the partially wet patterned substrate.

### CROSS-REFERENCE TO RELATED APPLICATIONS

This application claims the benefit of U.S. Provisional application U.S. Ser. No. 61/918,945, provisionally filed on Dec. 20, 2013, entitled “A METHOD FOR DEPOSITING AND CURING NANOPARTICLE-BASED INK”, in the names of Michael J. Carmody, Richard J. Dixon, Chu Wong Aaron Chan, Kai Man Kerry Yu, Hsin-Yi Sherry Tsai, Glenn Shackleford, and Janet Heyen, incorporated herein in its entirety.

### FIELD OF THE INVENTION

This invention relates in general to an apparatus and method for forming a pattern on a substrate by depositing a nanoparticle ink onto the substrate, and sintering the ink using concentrated light energy and more particularly to formulation and curing of a nanoparticle ink with favorable conductivity.

### BACKGROUND

Fabrication of mass-produced electronic items typically involves temperature- and atmosphere-sensitive processing. Conventional material deposition systems for electronic fabrication, including plasma-enhanced chemical vapor deposition PECVD and other vacuum deposition processes, rely on high temperatures and rigidly controlled ambient conditions. Conventional processes for circuit board manufacture are typically subtractive, applying a conductive or other coating over a surface, treating the coating to form a pattern, then removing unwanted material. The conventional method for forming copper traces is one example of this process, requiring multiple processing steps, with the use of toxic chemicals for etching and the complications and cost of proper waste disposal.

Recent advances in printed electronics provide solutions that reduce the cost, complexity, and energy requirements of conventional deposition methods and expand the range of substrate materials that can be used. For printed electronics, materials can be deposited and cured at temperatures compatible with paper and plastic substrates and can be handled in air. In particular, advances with nanoparticle-based inks, such as silver, copper, and other metal and semiconductor nanoparticle-based inks, for example, make it feasible to print electronic circuit structures using standard additive printing systems such as inkjet and screen printing systems. Advantageously, due to their very small particle sizes, nanoparticle-based inks have lower curing temperatures than those typically needed for bulk curing where larger particles of the same material are used.

Commercially available systems for curing nanoparticles typically employ heat from convection ovens or Xenon flash illumination energy. In such illumination systems, the Xenon lamps emit pulsed light that is directed onto films of nanoparticles to be cured. High light energy levels are required for nanoparticle curing. Exemplary nanoparticle-based inks such as Intrinsiq Material Ltd. CI-002 ink, a copper nanoparticle based inkjet ink, or CP-001 paste, a copper nanoparticle-based screen print ink, can be sintered through the use of photonic energy from Xenon lamp or other illumination, provided that the illumination system delivers adequate energy to volatilize coatings used in the ink formulations and to sinter and cure the inks over large surface areas.

Conventional approaches for conditioning of the nanoparticle material, however, suffer from a number of deficiencies. Xenon lamp emission energy is characteristically distributed over a broad range of wavelengths and often includes wavelengths that can cause unwanted effects, even at non-peak energy levels. This inherent spectral spread in Xenon lamp emission can have effects that result in incomplete or uneven curing. One result can be limited penetration of light energy into thicker films or premature sealing of top surface layers, trapping unwanted organic species in the remaining structure. This type of problem can occur when higher frequency light, such as light energy from the tail of the spectral distribution curve, inadvertently sinters the film and renders its top layers opaque to other wavelengths of emitted Xenon light, delaying or preventing complete curing of the lower layers. When this happens, the binder or organic suspension in which nanoparticles are suspended is only partially removed, causing uneven sintering, which can limit the conductivity of the applied materials.

With Xenon light, the distribution of energy intensity is non-symmetrical; the co-lateral dispersive energy that is produced can reduce curing efficiency or may even cause overheating and damage to the substrate. Further, pulsing of the Xenon lamp or other light source tends to create high energy peaks that can ablate films rather than melt and reflow films. As a result, the cured product may not have the desired structure.

Conventional methods are also limited with respect to the number of substrates that can be used. With materials having high thermal conductivity, such as aluminum, silicon, and ceramics, the applied energy intended for curing may dissipate too quickly. With such materials, heat can be drawn away from the area of incident light before sintering occurs. Furthermore, particular wavelengths emitted from the Xenon lamps can damage some polymeric films and other substrates, making them less suitable for curing. Adhesion to various substrates is also a problem; relatively poor adhesion of existing methods and formulations limits the number of substrates that can be used.

Performance provided by printing methods is encouraging, but there is considered to be room for improvement. One goal is to approximate more closely the conductivity of copper traces that are applied when using conventional photolithographic/etching methods. Conventionally formed copper traces have a resistivity of about 1.7 μΩcm; this provides a reference value against which relative conductivity of a material is compared. The “bulk ratio” is a multiple of this resistivity and is used as a practical measure of how well a conductive trace performs. In conventional practice as of the date of this application, printed traces formed from nanoparticle copper have been shown to achieve bulk ratios no better than about 6× (that is, no lower than 6 times 1.7 μΩcm). Claims by researchers to achieving lower values of bulk resistivity have not been substantiated. Even improvements that achieve incremental improvements in bulk ratio would be considered to be extremely useful.

Barriers to improved performance include limitations on how much energy can be applied in sintering without degrading the porosity of the finished material. Higher levels of sintering energy would be advantageous, but conventional formulations limit the amount of energy that can be applied.

In conventional practice, all solvent materials must be dissipated prior to sintering, so that the applied traces are fully dry before heat energy is applied. If the applied ink is not fully dried, porosity increases and, consequently, resistivity increases as trapped solvent is vaporized by the photonic energy. Because trace solvents have been shown to cause problems with the sintering process, it is standard procedure to dry the applied ink as fully as possible prior to treatment with sintering energy. This extends the overall processing time that is needed for printed nanoparticle traces.

Thus, it can be seen that there is a need for improved methods for formulating and processing nanoparticulate inks and similar materials.

### SUMMARY OF THE INVENTION

It is an object of the present invention to advance the art of formulating and curing nanoparticle-based inks. With this object in mind, embodiments of the present invention provide a method for forming a conductive pattern on a substrate, the method comprising:
depositing, onto a surface of the substrate, a nanoparticle ink that comprises nanoparticles of a conductive or semiconductor material, at least one low boiling point solvent, and from 0.1 weight % to 50 weight % of a high boiling point solvent;
forming a partially wet patterned substrate by drying the deposited nanoparticle ink to a wetness range between about 3 weight % and 8 weight % solvent; and
directing a patterned illumination of laser light to form a cured deposited ink pattern on the partially wet patterned substrate.

According to an alternate aspect of the present disclosure, an embodiment of the present disclosure provides a method for forming a conductive pattern on a substrate, the method comprising:
depositing, onto a surface of the substrate, a nanoparticle ink that comprises coated copper nanoparticles, at least one low boiling point solvent, and from 0.1 weight % to 50 weight % of a high boiling point solvent;
forming a partially wet patterned substrate by drying the deposited nanoparticle ink to a wetness range between about 3 weight % and 8 weight % solvent; and
directing a patterned illumination of laser light to form a cured deposited ink pattern on the partially wet patterned substrate.

These and other aspects, objects, features and advantages of the present invention will be more clearly understood and appreciated from a review of the following detailed description of the preferred embodiments, and by reference to the accompanying drawings.

### BRIEF DESCRIPTION OF THE DRAWINGS

FIG. 1A is a flow chart showing a sequence for printing and curing nano-materials for electronic applications, according to an embodiment of the present invention.

FIG. 1B is a graph that shows comparative drying times for different nanoparticle-based ink formulations.

FIG. 2 is a schematic diagram showing a printing and curing system for use with electronic ink.

FIG. 3 is a schematic diagram showing a printing and curing system for use with electronic ink, wherein printing and illumination apparatus move past a stationary substrate.

FIG. 4 is a schematic diagram that shows components of an illumination apparatus for a printing and curing system using a bank of laser diodes.

FIG. 5 is a table showing results for different exemplary ink formulations.

FIGS. 6A, 6B, 6C, 6D, 6E, 6F, and 6G show scanning electron microscope (SEM) images and porosity images for ink formulated and cured, including examples showing embodiments of the present invention.

FIG. 7 is a table showing porosity obtained for the formulations given in FIG. 5.

### DETAILED DESCRIPTION OF THE INVENTION

The following is a detailed description of the preferred embodiments of the invention, reference being made to the drawings in which the same reference numerals identify the same elements of structure in each of the several figures. It is understood that the elements not shown specifically or described may take various forms well know to those skilled in the art.

Where they are used, the terms “first”, “second”, and so on, do not necessarily denote any ordinal or priority relation, but may be used for more clearly distinguishing one element or time interval from another.

In the context of the present disclosure, the term “ink” is a term of art that broadly applies to a material that is deposited in a pattern on a substrate in a viscous, generally fluid or paste form and is sintered and otherwise cured after deposition and drying by applying a curing energy such as heat or light energy. Sintering is a curing process by which curing energy effects a structural change in the composition and/or arrangement of particles in the ink.

In the context of the present disclosure, bulk ratios are expressed with an appended “×”, so that, for example, a material with about twice the resistivity of conventionally formed copper traces is expressed as having a bulk ratio of “2×”.

Curing may also have additional aspects for ink conditioning, such as sealing or removal of organic coatings or other materials that are provided in the ink formulation but not wanted in the final, printed product. In the context of the present invention, the term “curing” is used to include drying, sintering, and any post-sintering processing as well as other curing processes that apply light energy for conditioning the deposited ink.

The terms “nanoparticle-based material”, “nanoparticle-based ink”, “nanoparticle material”, “nanoparticle ink”, or “nanoparticulate material” refer to an ink or other applied viscous fluid that has an appreciable amount of nanoparticulate content, such as more than about 5% by weight or volume.

In the context of the present invention, the term “substrate” refers to any of a range of materials upon which the nanoparticle ink is deposited for curing. Exemplary substrates include polymers such as plastics; textiles; paper; sheet materials; metals; ceramics; and other materials that provide a suitable surface for depositing a pattern of nanoparticle-based ink. Substrates can be flexible or rigid.

As used herein, the term “energizable” relates to a device or set of components that perform an indicated function upon receiving power and, optionally, upon receiving an enabling signal.

The background section outlines a number of problems with conventional methods for sintering using Xenon light and other broadband light energy. Embodiments of the present invention address the problem of curing and sintering for nanoparticle-based materials using an array of one or more diode lasers, preferably arranged in series or in parallel. Each laser in the array emits a continuous or quasi-continuous beam for nanoparticle curing. According to embodiments of the present invention, the laser diode array is arranged so that the emitted laser energy extends across the width of a substrate, allowing single-pass curing of high volumes of material. Alternate embodiments enable curing in a swath that does not fully extend across the width of the substrate.

Embodiments of the present invention combine aspects of nanoparticle-based ink formulation with curing and sintering operations in order to achieve conductive traces of superior conductivity and adhesion. Results obtained using the formulation and processing described herein have achieved bulk ratios lower than 3×, approaching more closely the conductivity of copper traces than has been achieved with conventional methods.

### Formulation

Embodiments of the present invention can use copper nanoparticles coated with a polymer or, alternately, a combination of copper nanoparticles coated with polymer and copper/copper-oxide (Cu:CuO) nanoparticles that have a copper core with a CuO shell or coating and about 8% PVP (Polyvinylpyrrolidone) dispersant. In the context of the present disclosure, the phrase “copper oxide nanoparticles” is equivalently used for copper/copper-oxide (Cu:CuO) nanoparticles. Nanoparticles formed from other metal and semiconductor materials can alternately be used.

The ink is advantageously prepared in a solvent that contains a sintering enhancer, such as about 5 weight % of glycerol. Alternately, some other solvent having a high boiling point above about 200 degrees C. and a low vapor pressure below about 2 mm mercury at 20 degrees C. can be used, with a liquid or solid sintering enhancer in place of some or all of the glycerol content. Glycerol, with a vapor pressure of about 1 mm at 20 degrees C., appears to work well. Alternative sintering agents can include solid additives that may be non-volatile but are vaporized when sintering energy is applied.

In the context of the present disclosure, a “high boiling point” solvent is a solvent material having a boiling point (b.p.) in excess of about 200 degrees C. A “low boiling point” solvent has a boiling point below 200 degrees C. The high boiling point solvent can be glycerol (b.p. 290 degrees C.) or can be taken from the group consisting of 1,2-dodecanediol; 1,2-decanediol; N-methylpyrrolidone; diethylene glycol; diethylene glycol monoethylether; diethylene glycol monobutylether; diethylene glycol monoethylether acetate; diethylene glycol monobutylether acetate; dipropylene glycol; dipropylene glycol monobutylether; and 2-methyl-2,4-pentanediol. Low boiling-point solvents that can be used include ethanol; butanol; 2-methoxyethanol; 1-propanol, 2-propanol; and 1-methoxy-2-propanol, for example.

Table 1 lists formulations for the conventional comparative examples and for example embodiments of the present invention that are described herein. Percentages in Table 1 and in this disclosure are weight % unless specifically noted otherwise.

The glycerol or other sintering enhancer can be added at any stage in the ink formulation, such as during mixing before high shear or during ultrasonic processing. The added sintering enhancer does not appear to affect the stability of the formulation.

It can be appreciated that using a solvent of this type in the formulation extends the drying time over that conventionally used for conductive ink application. Thus, when following conventional sintering practices, solvent composition of this type would be considered an undesirable feature of an ink formulation. However, instead of requiring an extended drying time due to the added glycerol, embodiments of the present invention reduce the drying time when compared with conventional processing methods. Advantageously, given the formulations shown in D, E, F, and G of Table 1, the printed traces are ready for sintering when not yet fully dry. Subsequent examples describe particular dryness levels for the applied nanoparticle-based inks prior to sintering.

The printed electronic structures that can be formed by the present method are made of a metal or semi-metal, such as semiconductor material. Suitable metals for printing and curing in a pattern include, but are not limited to, copper, gold, silver, nickel, and other metals and alloys. Semi-metal materials including silicon can also be used. Furthermore, silicon particles that have been doped to provide semiconducting behavior (for example, doped with phosphorous or arsenic) are also suitable. Therefore, the present method can be used in production of both electronic structures, such as connecting traces between devices, and semiconducting devices themselves.

The nanoparticle ink used in embodiments of the present invention comprises the metal or semi-metal with a binder or coating (typically organic). The binder or coating in the ink helps to prevent agglomeration and to maintain the surface area, which confers many of the advantageous properties of nanoparticles. The nanoparticles used in the ink formulation can be between 0.5-500 nm diameter. Advantageously, therefore, the present invention can be implemented for a wide range of nanoparticle inks including those with larger particles which are often cheaper to produce.

The high surface area of the nanoparticles is advantageous, so that the energy required to transform the nanoparticles in the ink, such as by sintering or curing, is less than for bulk materials. Therefore, as the laser illumination not only removes the coating or binding materials in the ink formulation, it also causes a transformation of the material.

TABLE 1
Formulations for Comparison

| Reference | | |
|---|---|---|
| formulation | Nanoparticle content | Solvent |
| A | Cu, coated, 8.9% PVP | 40 wt % Ethylene glycol (b.p. 197° C.); |
| | | 60 wt % Ethanol (b.p. 78° C.) |
| B | Cu, coated, 5.5% PVP | 40 wt % Ethylene glycol (b.p. 197° C.); |
| | | 60 wt % Ethanol (b.p. 78° C.) |
| C | CuO, 8% PVP | 60 wt % Ethylene glycol (b.p. 197° C.); |
| | | 20 wt % Butanol (b.p. 119° C.); |
| | | 20 wt % 1-Methoxy-2-propanol (b.p. 120° C.) |

Novel formulations follow

| | | |
|---|---|---|
| D | Cu, coated, 8.9% PVP | 35 wt % Ethylene glycol (b.p. 197° C.); |
| | | 60 wt % Ethanol (b.p. 78° C.) |
| | | 5 wt % glycerol (b.p. 290° C.) |
| E | CuO, 8% PVP | 55 wt % Ethylene glycol (b.p. 197° C.); |
| | | 20 wt % Butanol (b.p. 119° C.); |
| | | 20 wt % 1-Methoxy-2-propanol (b.p. 120° C.) |
| | | 5 wt % glycerol (b.p. 290° C.) |
| F | Ratio 9:1 | 35 wt % Ethylene glycol (b.p. 197° C.); |
| | Cu, coated, 8.9% PVP | 60 wt % Ethanol (b.p. 78° C.) |
| | and CuO, 8% PVP | 5 wt % glycerol (b.p. 290° C.) |
| G | Ratio 2:1 | 35 wt % Ethylene glycol (b.p. 197° C.); |
| | Cu, coated, 8.9% PVP: | 60 wt % Ethanol (b.p. 78° C.) |
| | CuO, 8% PVP | 5 wt % glycerol (b.p. 290° C.) |

NOTE to Table 1: for formulations D, E, F, G, other solvents than those listed can be substituted as low boiling point solvents.

Upon receiving the illumination energy, the individual metal/semi-metal nanoparticles bond to form a metal/semi-metal structure, in the form of a densified metal or semi-metal film (depending on the material of the nanoparticle ink). As the laser illumination can be focused to a small spot size, the metal structure that is formed is localized to areas impacted by the laser. The high degree of accuracy with which the laser can be directed results in the formation of the high resolution printed structures.

### Overview of Processing Steps

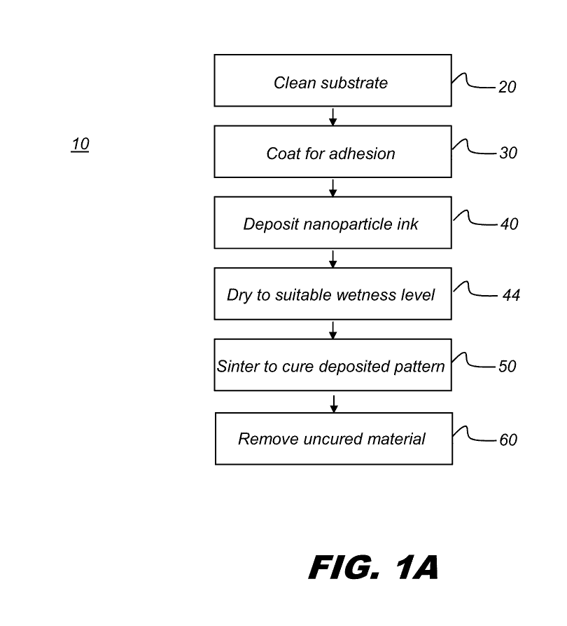

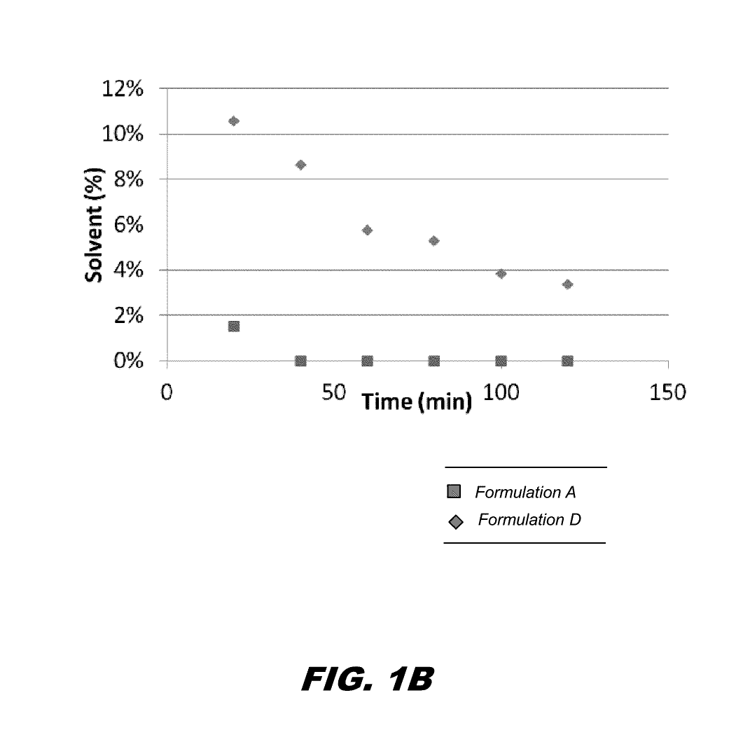

The flow diagram of FIG. 1A shows a sequence of steps for a printing and curing method 10 for nanoparticle-based inks according to an embodiment of the present invention. This method includes: pretreating the substrate in a conventional washing or cleaning step 20, depositing adhesion promoting material in an optional coating step 30, depositing a pattern of nanoparticle ink in a printing step 40; partially drying the deposited ink to a desired wetness level in a partial drying step 44; illuminating the pattern of deposited ink to transform the ink by sintering and other curing processes using a laser, multiple lasers, or a laser diode array in a curing step 50; and removing the untransformed ink and residual materials in a removal step 60. Removal step 60 also includes evaporating and exhausting excess material from the applied and cured ink or coating.

### Preparation for Sintering in Partial Drying Step 44

Instead of requiring an extended drying time due to the glycerol, as would be expected, embodiments of the present invention shorten the drying time as compared with drying times typical of conventional processing methods. Shorter drying times are used because the applied traces are ready for sintering when not yet fully dry. The inventors have found that it is advantageous to reduce the time between printing and sintering so that a measurable amount of high boiling point solvent remains in the deposited ink when sintering energy is applied. Sintering energy is applied to a partially wet patterned substrate.

The graph of FIG. 1B shows comparative drying times under identical conditions for two of the different nanoparticle-based ink formulations listed in Table 1. Drying conditions are at room temperature and under vacuum for the examples shown. Conventional formulation A uses the standard solvent constituents, without glycerol or other sintering enhancer, and dries fully within about 40 minutes. That is, after about 40 minutes, there is no appreciable solvent remaining in the applied ink. Formulation D, on the other hand, dries much more slowly, still having more than 5% solvent composition, by weight, after drying for about an hour. Because of the higher boiling point of glycerol, it seems clear that the bulk of the remaining solvent in the deposited ink is glycerol after drying for about 20 minutes, as shown in FIG. 1B.

The inventors have found that sintering once the solvent percentage is lower than about 8% and exceeds at least about 3% provides significantly improved conductivity over conventional approaches that require a fully dried ink for sintering. Thus, even though a high boiling point solvent is used in the ink formulation, the drying time for sintering with the inventive formulations is within the range of drying times conventionally used where fully dry ink is required. Moreover, the inventors have found that there is a range of acceptable drying conditions, including drying at room temperature under at least partial vacuum, drying under ambient atmospheric pressure conditions, drying under applied heat, etc. In a particular application, the rate of drying, hence the time interval between printing and sintering, is adjusted so that the deposited ink on the substrate has from about 3-8% solvent composition, forming a partially wet patterned substrate.

### Sintering

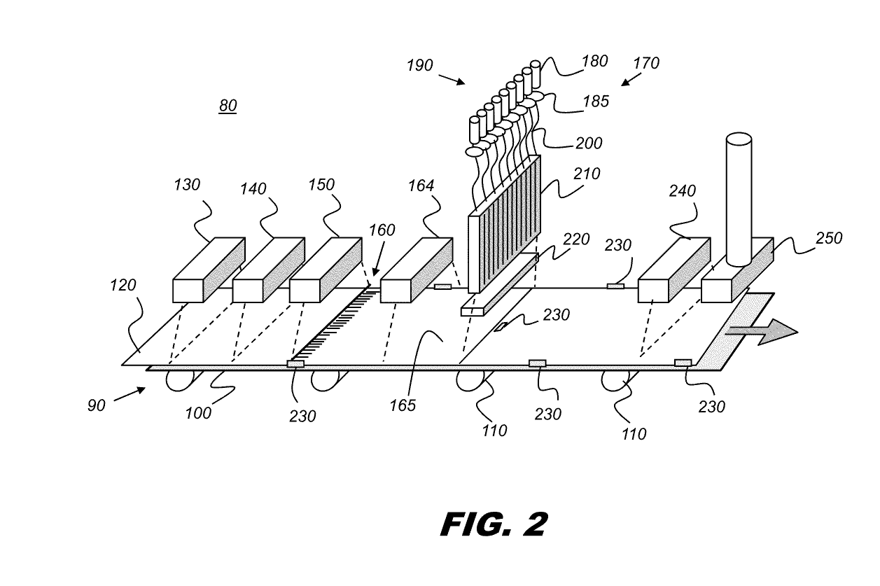

Laser energy is used for sintering the applied traces on the partially wet patterned substrate. By way of example, the schematic diagram of FIG. 2 shows a printing and curing system 80 according to an embodiment of the present invention. The printing and curing system 80 has a substrate 120 on which material is printed, a transport apparatus 90 with devices such as rollers 110 or other components for providing relative movement between printing and curing components and substrate 120, a mount for substrate 120 which may include a heat sink or temperature control element 100 designed to maintain substrate 120 at a suitable temperature at specific points in the process, an optional substrate cleaning apparatus 130, an optional coating apparatus 140, a printing apparatus 150 that is energizable for deposition of the nanoparticulate electronic material, such as using inkjet or screen print mechanisms, creating a pattern of printed elements 160 on the substrate 120 surface. An optional drying apparatus 164 provides the needed energy for partial drying of the printed elements 160, so that a percentage of solvent remains, as described previously. Drying apparatus 164 may provide heat energy, forced air, or vacuum to reduce solvent content to suitable levels for sintering, forming a partially wet patterned substrate 165 at the part of the processing shown in FIG. 2.

Continuing with the FIG. 2 process, an illumination apparatus 170 has two or more energizable laser diodes 180, each with its corresponding coupling optics 185 that direct light through a corresponding light guide, shown as an optical fiber 200. Light from fibers 200 goes through a coupling block 210 and to an illumination lens 220 for directing a pattern of illumination that corresponds to the pattern of printed elements 160 deposited on substrate 120. A washing apparatus 240 can be energized to perform a cleaning operation to remove uncured ink or other material. An exhaust element 250 is provided to help remove by-products of the printing and curing process.

Transport apparatus 90 more generally provides relative motion for forming a pattern and can also operate wherein substrate 120 is stationary and one or more of energizable surface conditioning, printing, and curing components, such as apparatus 130, 140, 150, 164, 170, 240, and 250 are swept along the surface of substrate 120 to perform pattern deposition and curing operations.

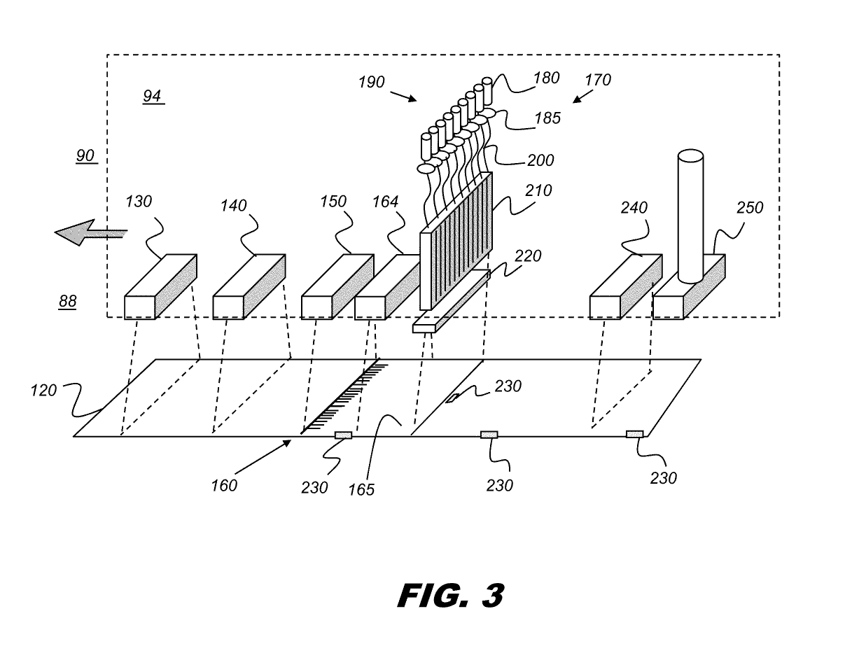

FIG. 3 is a schematic diagram showing an alternate embodiment with a printing and curing system 88 for use with electronic ink, wherein printing apparatus 150, optional drying apparatus 164 and illumination apparatus 170 and other components are coupled together as part of a pattern forming apparatus 94 that moves past a stationary substrate 120. Transport apparatus 90 may include a leadscrew or may be belt-driven, for example. A dashed box indicates pattern forming apparatus 94. Transport apparatus 90 moves pattern forming apparatus 94 from right to left across substrate 120 in the arrangement of FIG. 3.

It can be appreciated that the printing and sintering apparatus embodiments of FIGS. 2 and 3 are exemplary only and admit any of a number of variations for directing a pattern of laser energy toward the deposited conductive traces formed on partially wet patterned substrate 165.

Washing or cleaning step 20 in the sequence of FIG. 1A consists of cleaning the substrate with solvents, or alternately with surface treatments such as using corona discharge energy or treating with compressed gases or other methods. It is found that the method of the present invention is particularly suitable for, but not limited to, use with a number of substrates including PET (polyethylene terephthalate), PI (Polyimide), PE (polyethylene), PP (Polypropylene), PVA (poly-vinyl alcohol), SiN (silicon nitride), ITO (indium tin oxide) and glass. In general, substrates need to be sufficiently clean in order to fully accept and cure the printed ink materials. Failure to clean the substrate, either in line, by energizing substrate cleaning apparatus 130 as depicted in the process of FIG. 2, or prior to printing using some other method, can lead to poor adhesion, degraded electrical performance, material contamination, and breakage.

According to an embodiment of the present invention, the substrate 120 material is transported by means of transportation apparatus 90 (FIG. 2) and moved through system 80 in a roll-to-roll, flat, sheet-fed, drum-fed, continuous, or stop-and-start sequence. Along the transportation system are placed one or more optional tracking elements such as reflectors or sensors 230. Tracking elements provide optical or electrical feedback as to the alignment of the elements of the printing chain. For example, reflections of a tracking element in the curing process can determine curing accuracy and substrate position. Sensors 230 can be placed under the substrate in the assembly or along edges of the substrate, as long as the illuminating wavelength reaches the sensor 230.

Optional temperature control element 100 (FIG. 2) may be a simple heat sink or may be an apparatus designed to heat and cool the substrate to a desired temperature, integrated into transport apparatus 90. Maintaining temperature may be a concern where heated substrates can expand or shrink under different temperature conditions, with the risk of deformation of substrate or end-printed structures. Furthermore, as heat energy from the illumination apparatus 170 can cause spatial temperature variations, spatially varying the temperature may be useful for certain applications.

Optional coating step 30 in the FIG. 1A sequence prepares the surface with adhesion promoting materials. Coatings, applied by energizing coating apparatus 140 in FIG. 2, can be uniformly deposited, such as by aerosol application, roll coating, or other methods. Alternately, coatings are deposited selectively by inkjet deposition, or other selective printing mechanism, such as aerosol jet. This step, while not required in all cases, can significantly enhance the ability of material to adhere to substrate 120. Selective deposition of adhesion promoting materials can further assist in delineation between electrically active printed electronic structures and passive sections of a printed region.

Continuing with the FIG. 1A sequence, the nanoparticle ink is deposited onto the substrate in printing step 40. The ink is deposited by energizing nanoparticle ink printing apparatus 150. Nanoparticle ink printing apparatus 150 uses a suitable deposition method such as ink-jet, offset-lithography, screen printing, indirect or direct gravure, flexography, aerosol application, or some other method. The binder and/or coating present in the nanoparticle ink helps to provide an even distribution of the ink. The deposited layer can be of variable thickness and, in practice, is typically in the thickness range between about 0.05-50 μm, but would not be limited to this range.

Auxiliary drying equipment, not explicitly shown in the FIG. 2 or 3 embodiments, may also be provided to facilitate drying or solidifying of an applied coating.

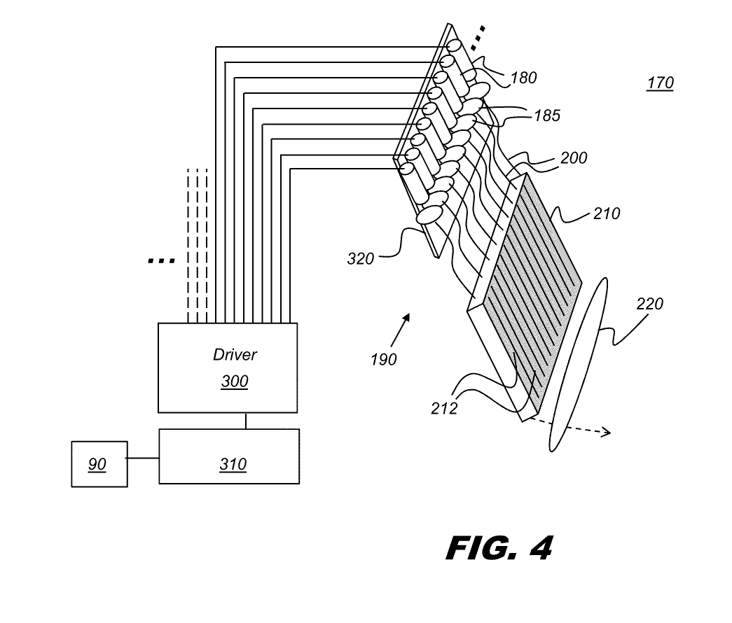

As shown in the perspective view of FIG. 4, drivers 300, under control of a control logic processor 310, provide the energizing signals for the individual laser diode 180 in each channel in illumination apparatus 170. A small number of laser diodes 180 are shown in FIG. 4. In embodiments of the present invention, numerous laser diodes 180 can be employed. Laser diodes 180 are provided with an optional heat sink 320. Each laser diode 180 has corresponding coupling optics 185. An optical fiber 200 or other light guide then directs the generated laser light through coupling block 210 and lens 220. The laser diode 180 in each channel can be independently energized or de-energized as needed. This allows illumination apparatus 170 to direct light in a pattern, in conjunction with the operation and speed of transport apparatus 90. Advantageously, the pattern of illumination that is provided corresponds to the pattern of nanoparticle material that is applied by nano ink printing apparatus 150.

The use of laser light allows for the selection of a light wavelength that is well suited for the sintering of the nanoparticles while eliminating or minimizing damage to the coating. By using lasers, embodiments of the present invention apply monochromatic light to the substrate at wavelengths most favorable to sintering and other curing functions, without contributions from other wavelengths, such as lower wavelength light that can be heavily absorbed in the upper layers of deposited material. As noted earlier, absorption of wavelengths in upper layers nearest the surface can cause these upper layers to be inadvertently sealed, trapping binder and other materials that must be removed from beneath the surface. Advantageously, laser illumination provides sufficient energy for the removal of component materials in the precursor nanomaterial. This includes materials useful for improving ink application but not wanted in the final product, such as organic binders and particle coatings. With laser light, the spectral content and intensity can be specified and controlled so that the laser delivers the proper energy to the applied material, at the proper depth. In this way, problems such as unwanted sealing of top layers can be avoided.

According to an embodiment of the present invention, diode laser arrays are formed of diodes having different emission wavelengths, wherein the emission wavelengths of at least two of the laser diodes in the array differ from each other by more than 25 nm. By spacing optical fibers 200 in the coupling block 210, the subsequent illumination lens 220 accommodates accurate spot placement for each wavelength. There can be some trade-off of spot size verses proximity between the different wavelengths. The focal spot size can also vary as a function of wavelength.

Advantageously, separate laser channels can be addressed simultaneously or sequentially. With simultaneous addressing, printing relies on the difference in required curing wavelengths for different materials. For example, ink having high copper (Cu) content tends to cure with applied energy in the near infrared, whereas some inks high in silicon content cure uniformly using shorter wavelengths.

When driving laser diodes, pulse width modulation (PWM) can be used for controlling power levels and for temporally interspersing the illumination wavelengths. This permits the use of different wavelengths, both to cure different materials and to provide curing energy at different depths. For example, a longer wavelength can be useful for curing material at a greater depth. Wavelengths that have been found to be suitable for curing include, but are not limited to: 193 nm, 248 nm, 308 nm, 355 nm, 488 nm, 532 nm, 808 nm, 860 nm, 975 nm, 1064 nm, and CO₂ laser wavelengths.

Each deposited material or ink can have different curing properties, responding differently to light of various wavelengths and intensities. Where multiple materials are deposited, it may be suitable to cure the different materials under the same conditions or to vary wavelength and intensity levels appropriately. According to an embodiment using a single illumination apparatus 170 as in FIG. 2, for example, each laser diode 180 has the same wavelength, with variation in wavelength within the laser array to within no more than about +/−1 nm of a nominal wavelength, but the intensity of the directed illumination changes, depending on the spatial position of apparatus 170 relative to the substrate 120 surface. Individual laser diodes 180 can be energized at different power levels over different portions of the applied pattern of printed elements 160. Exposure duration can also be modified, such as by varying the transport speed of transport apparatus 90 or using pulse-width modulation, for example. According to an alternate embodiment of the present invention, laser diode array 190 has laser diodes 180 of different wavelengths, suitably positioned for providing energy to the applied pattern of printed elements 160. Formulation can be varied so that different formulations of nanoparticle-based inks are sintered using laser sources of different wavelengths provided from laser diode array 190.

With the addition of glycerol or other suitable high BP solvent, excess laser energy from sintering may be transferred to the task of decomposing the dispersant/binder, improving thermal transfer and leaving a highly conductive pattern.

### Substrate Considerations

Thermal characteristics of the substrate can complicate the task of sintering in a number of ways when conventional Xenon flash energy is used. Substrates having relatively high thermal conductivity, such as aluminum, silicon, and ceramic substrates, for example, can conduct the needed heat away from the area of incident light before sintering energy levels are reached. Polymer-based substrates, such as ITO coated plastic substrates, can be damaged due to the higher thermal conductivity of the ITO coating. Embodiments of the present invention help to address problems related to thermal response by using laser light that can be focused onto a small area.

It is found that the present method is particularly suitable for a number of substrates including PET (polyethylene terephthalate), PI (Polyimide), PE (polyethylene), PP (Polypropylene), PVA (poly-vinyl alcohol), SiN (silicon nitride), ITO (indium tin oxide) and glass. On such substrates, the present application provides an improved method for producing high resolution lines compared to other systems. In particular, the direct transformation (curing, sintering or otherwise) of the material by the laser allows for higher resolution features, reduces or avoids the need for adding further layers such as photoresist layers, and requires fewer stages to produce than do conventional methods. Printing and curing of electronic materials and components can be performed at low volumes as well as for large-scale, high volume production.

### Process Steps

The following process steps describe using copper nanoparticles; it should be noted that formulations with other conductor and semiconductor materials could alternately be used.

### 1. Ink Formulation.

### Disperse Cu Nanoparticle Ink in Solvent—

Cu nanoparticles (25 weight %) with a dispersing agent were mixed with ethylene glycol and ethanol at a ratio of (40:60). The suspension was high shear mixed at 5000 rpm for 1 hour. An ultrasonic horn was then used to break up any aggregates for 1 hour with chilled water to minimize solvent evaporation from overheating. This ink was filtered through a 1.2 um filter.

Blend Cu Nanoparticle Ink with Glycerol—

0.1-50 weight % of Glycerol was added into the Cu nanoparticle ink. Agitation was used to mix the solvents for 1 min.

### 2. Ink Deposition.

Deposit Ink onto Substrate—

The blended Cu nanoparticle ink is deposited onto the substrate, such as by inkjet printing or other printing technique. The coatings are then partially dried in an oven or other drying apparatus, leaving only the high boiling point solvent component in the deposited ink, so that the ink is still considered to be wet. (Refer to the preceding description on ink drying given with reference to FIG. 1B).

### 3. Curing (Sintering).

### Laser Cure Cu Ink and Wash-Off—

The partially dried blended Cu nanoparticle ink is laser-sintered and cured. Remaining uncured areas are washed off. Washing is done, for example, using ultra-sonication.

Although the above process has been described with examples that us copper nanoparticles, this process would be applicable to nanoparticles using other materials. For example, ink formulation, deposition, and sintering can employ other conductive and semiconductor materials such as silver (Ag), gold (Au), palladium (Pd), platinum (Pt), nickel (Ni), silicon (Si), including doped silicon, alumina (Al₂O₃) and their combinations thereof. For each of these materials, solvent mixture, ink deposition, and sintering processes would follow similar steps as those described for copper nanoparticles, with corresponding changes according to the conductive or semiconductor materials used.

### Example 1

Cu nanoparticles (25 weight %) with a dispersing agent were mixed with ethylene glycol and ethanol at a ratio of (40:60). The suspension was high shear mixed at 5000 rpm for 1 hour. An ultrasonic horn was then used to break up any aggregates for 1 hour with chilled water to minimise solvent evaporation from overheating. This ink was filtered through a 1.2 um filter.

Glycerol (5 weight %) was added into the above formulation. The mixture then agitated for about 1 min to allow sufficient mixing of the solvents.

The blended Cu nanoparticle ink was spin-coated onto a glass substrate. The coating was then partially dried in an oven at 25° C. in vacuum for 100 mins.

The wet blended Cu nanoparticle ink was laser sintered and cured using a continuous wave 808 nm diode laser. Remaining uncured areas were washed off by ultra-sonication using H₂O/IPA (50:50) followed by a mixture of ethylene glycol/ethanol (40/60).

### Results

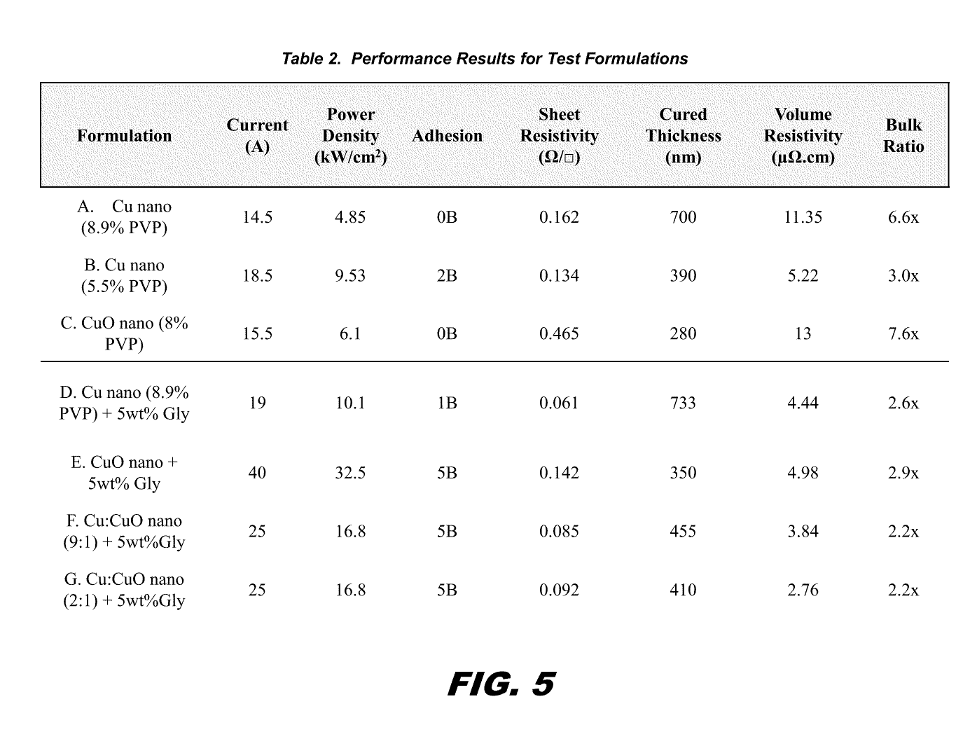

Table 2 in FIG. 5 shows results for power density, adhesion, resistivity, and overall conductivity for the formulations listed in Table 1 using the laser sintering provided in the method of embodiments of the present invention. Of particular interest are high power densities and low bulk ratio values and overall resistivity values for formulations D, E, F, and G.

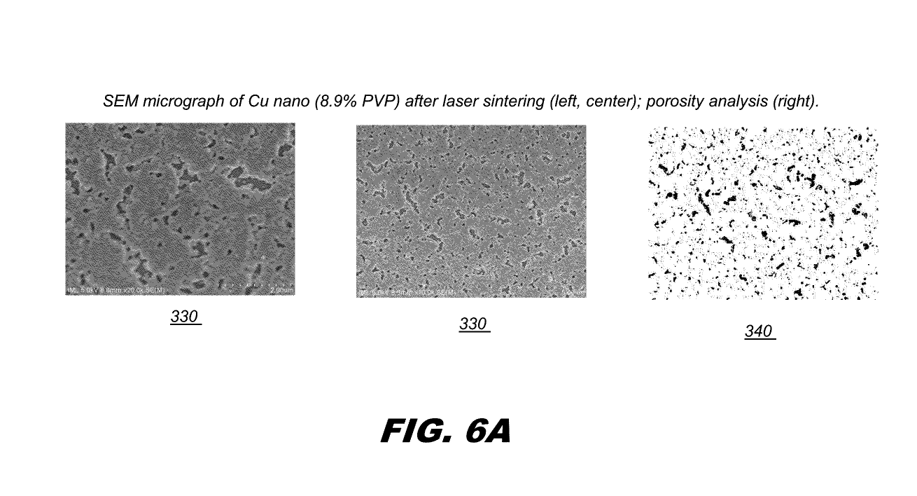

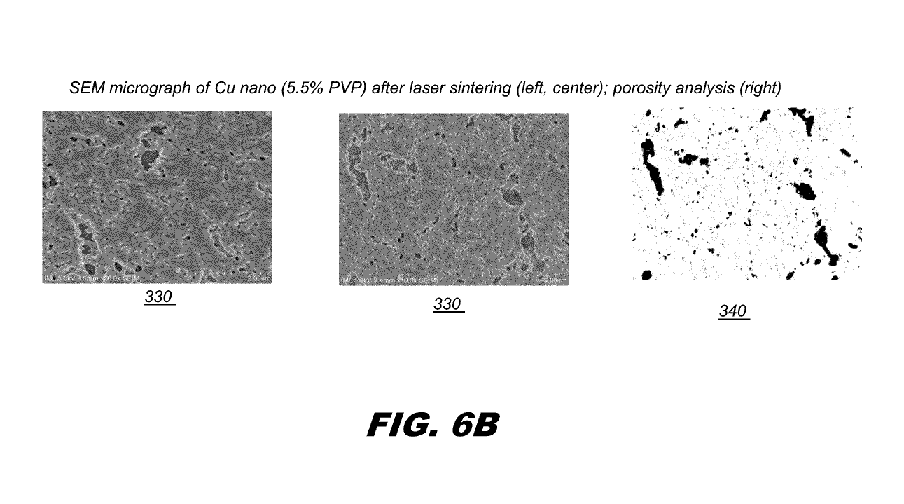

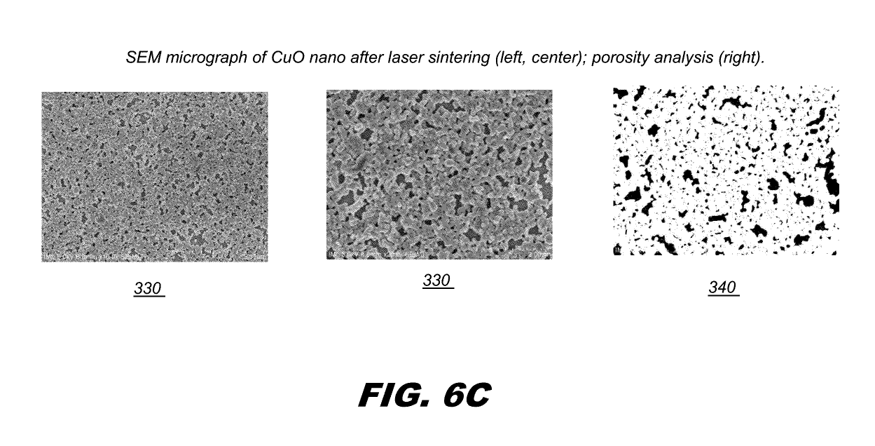

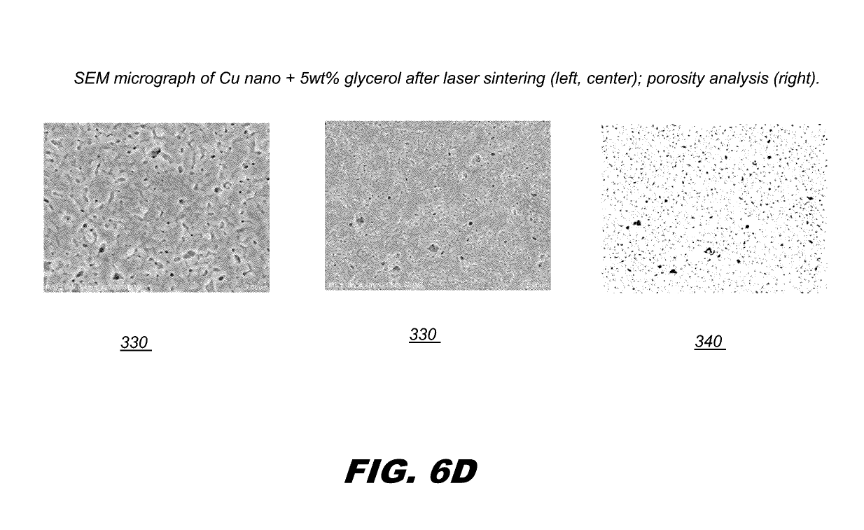

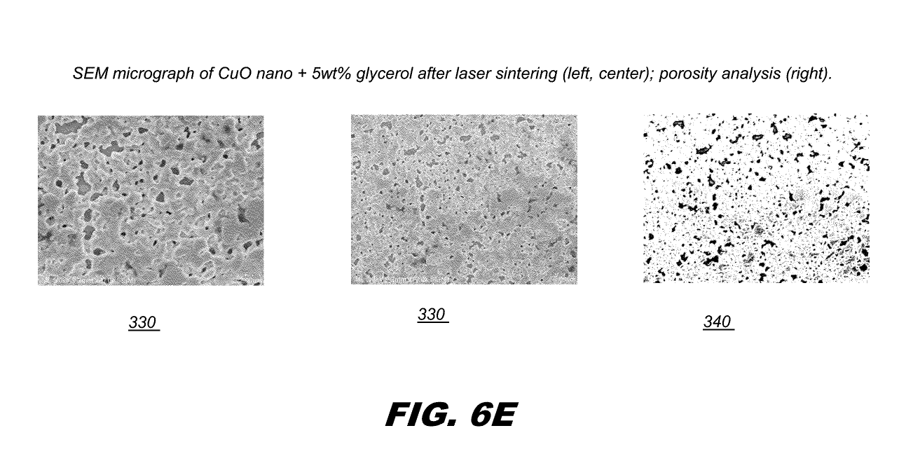

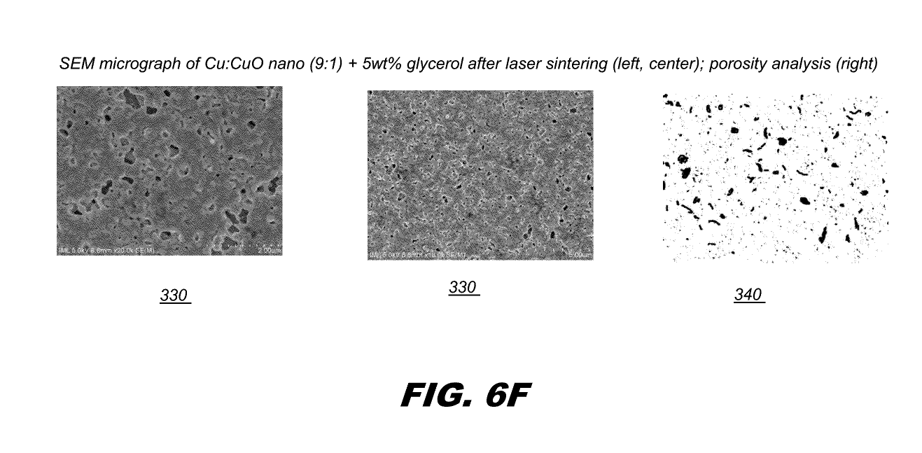

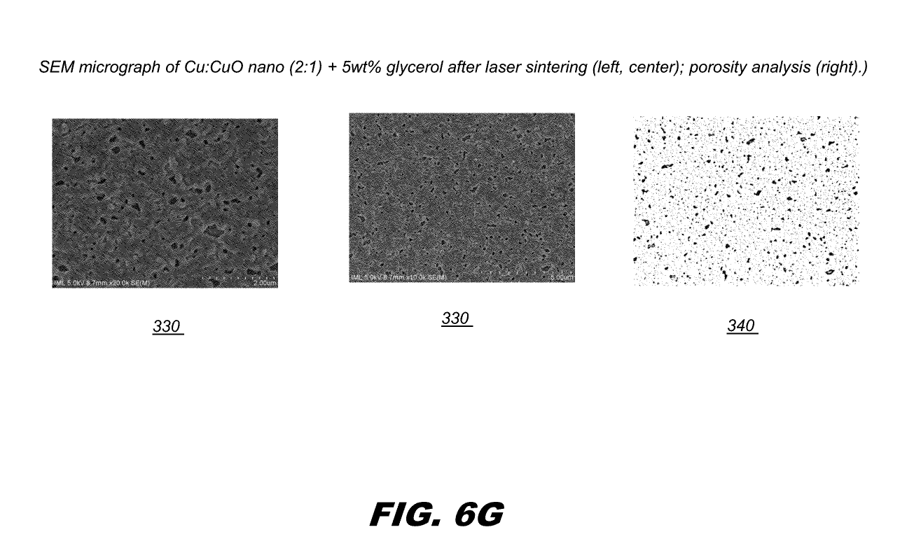

FIGS. 6A, 6B, 6C, 6D, 6E, 6F, and 6G show processing results for the corresponding A-G formulations of Table 1 processed according to an embodiment of the present invention. SEM micrographs 330 and a porosity analysis image 340 generated by processing the SEM image are shown for each of the seven formulations given in Table 1.

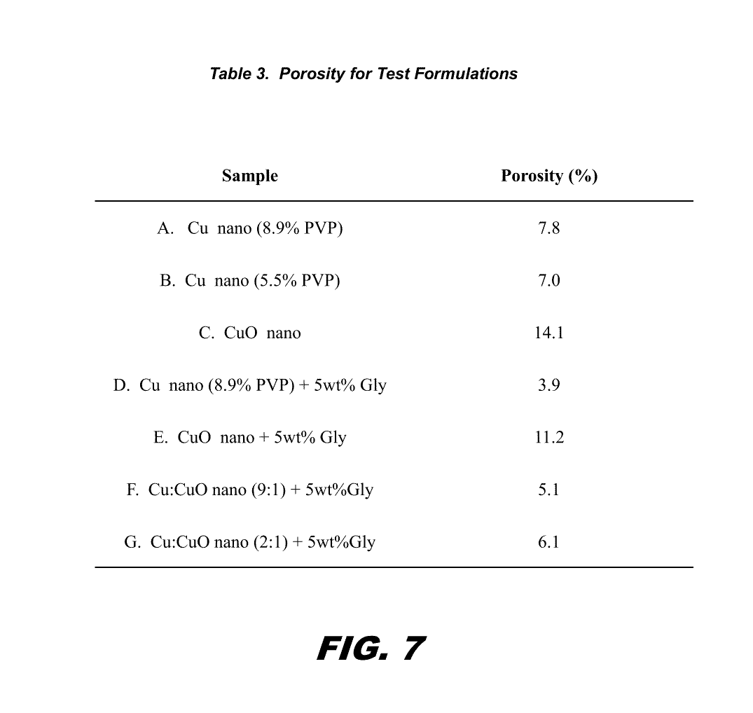

Table 3 in FIG. 7 compares porosity values achieved in processing the different formulations. Lower porosity values are generally preferable and, for conductive materials, indicate higher conductivity.

### Advantages

Addition of glycerol or other high boiling point solvent to existing Cu nanoparticle ink formulations provides a number of advantages, including the following:
(i) Reduced flaking by increasing the plasticity of the coating.
(ii) Improved adhesion, allowing an expanded range of substrates.
(iii) Significant increase in the power density threshold for applying sintering energy. This is advantageous for applying laser power to the Cu nanoparticles and helps to reduce the likelihood of ablation/oversintering. Without limitation to any particular theoretical explanation, glycerol appears to act as a thermal modulator as it evaporates during laser processing. This therefore increases the laser processing window.
(iv) Improved densification by reducing the porosity of sintered tracks.
(v) Poly alcoholic nature acts as a reducing agent to reduce CuₓO to metallic Cu (where x=1 or 2).
(vi) Improved viscosity (Glycerol has viscosity of 1412 Cp at 25° C.).

Measured results have shown that embodiments of the present invention significantly increase the level of conductivity that can be achieved using printed conductive traces. The inventors have shown the capability to routinely achieve 2-2.5× bulk Cu conductivity. Previous methods for forming conductive traces were unable to achieve better than about 6.6× bulk Cu conductivity.

Low vapor pressure means glycerol will remain in the coating at standard temperature and pressure.

Embodiments of the present invention enable reel-to-reel processing with on board printing, and fast curing without totally removing the solvent.

Referring again to the sequence of FIG. 1A, once the laser diode array 190 has finished illuminating the substrate and the desired image has been cured, the untransformed material is removed in removal step 60. The ink that has been scanned by the laser beam is transformed, typically by curing or sintering depending on the strength of the laser and length of exposure. The properties of the transformed, densified metallic structure differ from the untransformed structure. It is possible to select washing formulations and processes in removal step 60 to remove untransformed, unbounded, or uncured materials from the substrate surface while having little or no impact on cured regions. Such washing formulations are well known in the art of photolithography.

Embodiments of the present invention advantageously allow high resolution features to be produced in a single stage process. In particular, the invention avoids the need for an extra layer, such as a photoresist layer, and its subsequent processing. Furthermore, unlike photoresist methods, the method of the present invention does not require the use of etchants to remove the unprotected, uncured structure. This is advantageous as it simplifies the production process and greatly reduces costs related to waste handling. In addition, embodiments of the present invention allow a measure of accuracy with direct placement of electronic traces and structures. It is known, for example, that etchants used in conventional electronic patterning can result in excessively sloped tracks or undercut features, whereas the use of lasers to directly cure/transform the material allows for well-defined edges to be formed.

Some embodiments of the present invention provide a method for forming a conductive pattern on a substrate, the method comprising:
a) formulating a nanoparticle ink that comprises:
(i) copper nanoparticles coated with a polymer;
(ii) copper oxide nanoparticles, wherein the weight ratio of coated copper nanoparticles to copper oxide nanoparticles is 2:1 or greater;
(iii) at least one low boiling point solvent;
(iv) from 0.1 to 50 weight percent of a high boiling point solvent;
b) depositing the nanoparticle ink in a pattern on a surface of the substrate;
c) forming a partially wet patterned substrate by drying the deposited ink to a wetness range that lies between about 3 weight % and 8 weight % solvent; and
d) directing a patterned illumination of laser light to cure the deposited ink pattern on the partially wet patterned substrate.

According to an embodiment of the present invention, the high boiling point solvent is glycerol. The laser light sources can be laser diodes. The copper oxide particles can have a polymer coating.

The invention has been described in detail with particular reference to certain preferred embodiments thereof, but it will be understood that variations and modifications can be effected within the scope of the invention. For example, other high boiling point solvents can be used in place of glycerol.

1. A method for forming a conductive pattern on a substrate, the method comprising:
depositing, onto a surface of the substrate, a nanoparticle ink that comprises nanoparticles of a conductive or semiconductor material, at least one low boiling point solvent, and from 0.1 weight % to 50 weight % of a high boiling point solvent;
forming a partially wet patterned substrate by drying the deposited nanoparticle ink to a wetness range between about 3 weight % and 8 weight % solvent; and
directing a patterned illumination of laser light to form a cured deposited ink pattern on the partially wet patterned substrate.

2. The method of claim 1 wherein the nanoparticles comprise copper nanoparticles.

3. The method of claim 1 wherein the conductive or semiconductor material is taken from the group consisting of silver, gold, palladium, platinum, nickel, and silicon.

4. A method for forming a conductive pattern on a substrate, the method comprising:
depositing, onto a surface of the substrate, a nanoparticle ink that comprises coated copper nanoparticles, at least one low boiling point solvent, and from 0.1 weight % to 50 weight % of a high boiling point solvent;
forming a partially wet patterned substrate by drying the deposited nanoparticle ink to a wetness range between about 3 weight % and 8 weight % solvent; and
directing a patterned illumination of laser light to form a cured deposited ink pattern on the partially wet patterned substrate.

5. The method of claim 4 wherein at least a portion of the copper nanoparticles are coated with a polymer.

6. The method of claim 5 wherein the nanoparticle ink further comprises nanoparticles coated with copper oxide, wherein the weight ratio of polymer coated copper nanoparticles to copper oxide nanoparticles is 2:1 or greater.

7. The method of claim 4 wherein the high boiling point solvent has a boiling point that exceeds about 200 degrees C.

8. The method of claim 4 further comprising removing uncured deposited ink from the surface of the substrate following curing of the deposited ink pattern.

9. The method of claim 4 wherein the high boiling point solvent comprises glycerol.

10. The method of claim 4 wherein the high boiling point solvent is taken from the group consisting of 1,2-dodecanediol; 1,2-decanediol; N-methylpyrrolidone; diethylene glycol; diethylene glycol monoethylether; diethylene glycol monobutylether; diethylene glycol monoethylether acetate; diethylene glycol monobutylether acetate; dipropylene glycol; dipropylene glycol monobutylether; and 2-methyl-2,4-pentanediol.

11. The method of claim 4 wherein depositing the nanoparticle ink comprises using ink jet deposition.

12. The method of claim 4 wherein depositing the nanoparticle ink comprises printing.

13. The method of claim 4 wherein the substrate comprises a polymer.

14. The method of claim 4 wherein the substrate is taken from the group consisting of polyethylene terephthalate, polyimide, polyethylene, polypropylene, poly-vinyl alcohol, silicon nitride, indium tin oxide, and glass.

15. The method of claim 4 wherein the nanoparticle ink further comprises copper oxide nanoparticles and wherein the weight ratio of coated copper nanoparticles to copper oxide nanoparticles is 2:1 or greater.

16. The method of claim 4 wherein two or more different formulations of nanoparticle inks are deposited and wherein the patterned illumination uses lasers of two or more different wavelengths.

17. A method for forming a conductive pattern on a substrate, the method comprising:
a) depositing, on a surface of the substrate, a pattern of a nanoparticle ink that comprises:
(i) copper nanoparticles coated with a polymer;
(ii) copper oxide nanoparticles, wherein the weight ratio of coated copper nanoparticles to copper oxide nanoparticles is 2:1 or greater;
(iii) at least one solvent with a boiling point less than 200 degrees C.;
(iv) from 0.1 to 50 weight % of a solvent with a boiling point greater than 200 degrees C.;
b) forming a partially wet patterned substrate by drying the deposited ink to a wetness range that lies between about 3 weight % and 8 weight % solvent; and
c) directing a patterned illumination of laser light to cure the deposited ink pattern on the partially wet patterned substrate.

18. The method of claim 17 wherein depositing the nanoparticle ink comprises using ink jet deposition.

19. The method of claim 17 wherein drying is performed under at least partial vacuum.

20. The method of claim 17 wherein drying is performed under ambient atmospheric pressure conditions.
